(19) United States
(12) Patent Application Publication
(10) Pub. No.: US 2020/0312637 A1
(43) Pub. Date: Oct. 1, 2020

(54) PLASMA PROCESSING APPARATUS AND MAINTENANCE METHOD THEREOF

(71) Applicant: TOKYO ELECTRON LIMITED, Tokyo (JP)

(72) Inventors: Kazuhiro OOYA, Yamanashi (JP); Manabu KURODA, Yamanashi (JP)

(21) Appl. No.: 16/825,250

(22) Filed: Mar. 20, 2020

(30) Foreign Application Priority Data
Mar. 29, 2019 (JP) 2019-066990

(51) Int. Cl. H01J 37/32; C23C 16/50; C23C 16/458

(52) U.S. Cl. CPC H01J 37/32715; H01J 37/321; H01J 37/3288; C23C 16/50; H01J 2237/3321; H01J 2237/026; H01J 2237/20214; H01J 2237/20278; C23C 16/4583

(57) ABSTRACT

A plasma processing apparatus includes a processing chamber, a mounting table, a supporting shaft unit, a high frequency power supply and a high frequency shield. The mounting table mounts thereon a processing target in the processing chamber. The supporting shaft unit supports the mounting table from an opposite surface of a substrate mounting surface, has a protruding part that protrudes to the outside while penetrating through a wall of the processing chamber, and is connected to a rotation mechanism that rotates the mounting table about an axis. The high frequency power supply supplies a high frequency power for plasma processing. The high frequency shield covers the protruding part of the supporting shaft unit to suppress leakage of the high frequency power to the outside. The module unit is entirely detachable to divide each of the supporting shaft unit and the high frequency shield into parts in a longitudinal direction.

### CROSS-REFERENCE TO RELATED APPLICATIONS

This application claims priority to Japanese Patent Application No. 2019-066990, filed on Mar. 29, 2019, the entire contents of which are incorporated herein by reference.

### TECHNICAL FIELD

The present disclosure relates to a plasma processing apparatus and a maintenance method thereof.

### BACKGROUND

In manufacturing semiconductor devices, various processing such as film formation, etching, and the like are performed by supplying various processing gases to a semiconductor wafer (hereinafter, referred to as “wafer”) as a substrate. When such substrate processing is performed, plasma of the processing gases is supplied while rotating a mounting table disposed in a processing chamber and having the substrate mounted thereon. In a plasma processing apparatus for performing such plasma processing, various mechanisms for rotating the mounting table and converting the processing gases to the plasma are required.

For example, Japanese Patent Application Publication No. 2009-188161 discloses that a cover is disposed around a rotation shaft for rotating a boat where a plurality of substrates is mounted to shield electromagnetic waves when heating is performed using the electromagnetic waves.

In addition, Japanese Patent Application Publication No. 2016-21524 discloses an apparatus for performing plasma processing by irradiating microwaves to a processing gas in a processing chamber. In this apparatus, a bottom surface of a substrate holding mechanism for holding a substrate is supported by a supporting shaft connected to an external rotation mechanism while penetrating through the processing chamber. The plasma processing apparatus uses a magnetic fluid seal to hermetically close the space between the supporting shaft and the processing chamber, and thus is provided with a choke mechanism for preventing heating of the magnetic fluid seal due to the leakage of microwaves.

The present disclosure provides a plasma processing apparatus whose maintenance operation is simple, and a maintenance method thereof.

### SUMMARY

In accordance with an aspect of the present disclosure, there is provided a plasma processing apparatus for processing a substrate using plasma of a processing gas, comprising: a processing chamber where a processing gas supply unit configured to supply the processing gas is disposed; a mounting table disposed in the processing chamber and configured to mount thereon a substrate as a processing target; a supporting shaft unit configured to support the mounting table from an opposite surface of a substrate mounting surface, having a protruding part that protrudes to the outside while penetrating through a wall of the processing chamber, and connected to a rotation mechanism configured to rotate the mounting table about an axis; a high frequency power supply configured to supply a high frequency power for plasma processing; and a high frequency shield that covers the protruding part of the supporting shaft unit to suppress leakage of the high frequency power to the outside. Further, a module unit is configured to entirely detachable to divide each of the supporting shaft unit and the high frequency shield into parts in a longitudinal direction.

### BRIEF DESCRIPTION OF THE DRAWINGS

The objects and features of the present disclosure will become apparent from the following description of embodiments, given in conjunction with the accompanying drawings, in which:

FIG. 1 is a plan view of a substrate processing system including a plasma processing apparatus;

FIG. 2 is a longitudinal cross-sectional side view of the plasma processing apparatus;

FIG. 3 is a longitudinal cross-sectional side view of a supporting shaft unit of the plasma processing apparatus;

FIG. 4 is a longitudinal cross-sectional side view showing an internal structure of the supporting shaft unit;

FIG. 5 is a plan view showing a rotation mechanism of the supporting shaft unit;

FIG. 6 is an exploded view of the supporting shaft unit;

FIG. 7 explains a mechanism for detecting a rotation angle of a mounting table of the plasma processing apparatus;

FIG. 8 is a longitudinal cross-sectional side view showing a configuration example of an equipotential unit for suppressing electrolytic corrosion of a bearing disposed at the supporting shaft unit; and

FIG. 9 is a longitudinal cross-sectional side view showing another configuration example of the equipotential unit.

### DETAILED DESCRIPTION

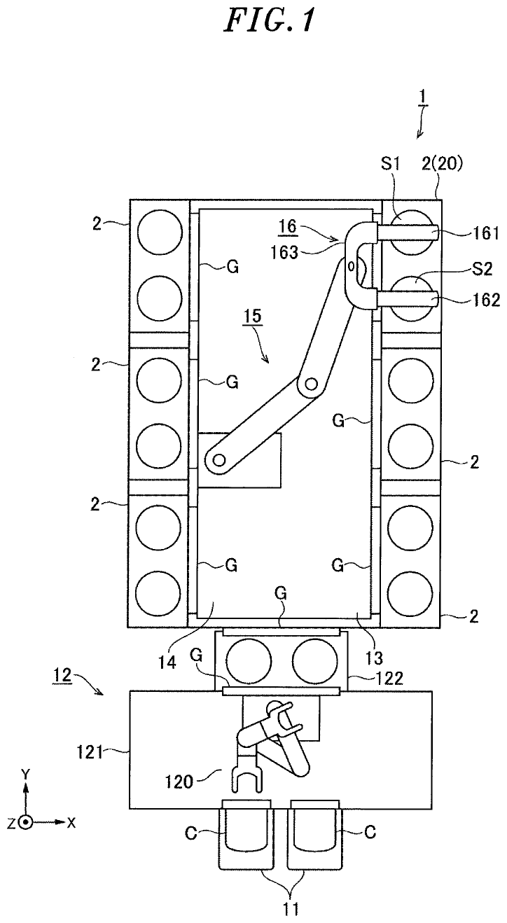

Hereinafter, a configuration example of a plasma processing apparatus 2 for forming a film on a substrate using plasma of a processing gas will be described as an embodiment of the present disclosure. Prior to the description of the detailed configuration of the plasma processing apparatus 2, a substrate processing system 1 of the plasma processing apparatus 2 will be briefly described with reference to FIG. 1.

In the substrate processing system 1 of this example, a carrier C containing a wafer W that is a circular substrate having a diameter of, e.g., 300 mm, is mounted on a loading/unloading port 11. A transfer unit 120 is disposed in a loading/unloading module 12 having a normal pressure atmosphere, and transfers the wafer W from the carrier C to a load-lock chamber 122. An atmosphere in the load-lock chamber 122 can be switched between a normal pressure atmosphere and a vacuum atmosphere.

A vacuum transfer module 13 connected to the load-lock chamber 122 includes a vacuum transfer chamber 14 having a vacuum atmosphere. A substrate transfer mechanism 15 is disposed in the vacuum transfer module 13 and receives the wafer W from the load-lock chamber 122 in the vacuum atmosphere.

As shown in FIG. 1, the vacuum transfer module 13 of this example is formed in, e.g., a rectangular planar shape having long sides in a front-rear direction. A plurality of, e.g., three plasma processing apparatuses 2 are connected to each of sidewalls corresponding to the long sides of the rectangular vacuum transfer chamber 14 which face each other. As will be described later, the plasma processing apparatus 2 of this example can perform plasma processing on a plurality of, e.g., two wafers W simultaneously in a vacuum atmosphere.

A gate valve G is used to open/close the space between the loading/unloading module 12 and the vacuum transfer module 13 and the space between the vacuum transfer module 13 and the plasma processing apparatus 2.

As shown in FIG. 1, the substrate transfer mechanism 15 includes a substrate holding unit 16 configured as a multi-joint arm for holding the wafer W. The substrate holding unit 16 includes a first substrate holder 161 and a second substrate holder 162. The substrate holders 161 and 162 are disposed at a leading end of the above-described multi joint arm and are connected to a connection portion 163 at base ends thereof to constitute the substrate holding unit 16.

The substrate transfer mechanism 15 moves into the plasma processing apparatus 2 while holding the two wafers W respectively on the first substrate holder 161 and the second substrate holder 162.

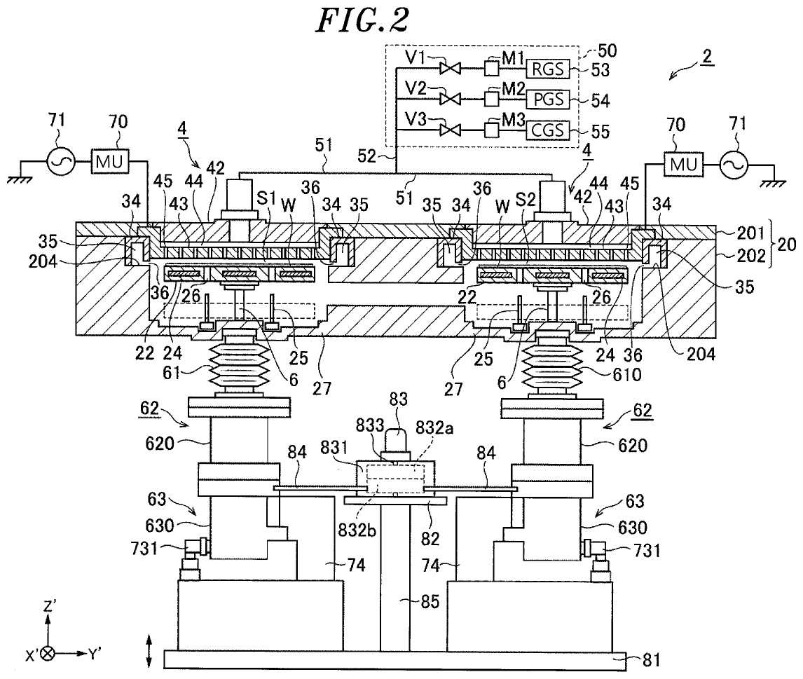

Hereinafter, a configuration example of the plasma processing apparatus 2 for performing plasma chemical vapor deposition (CVD) will be described with reference to FIG. 2. In addition to the coordinates (X-Y-Z coordinates) indicating the arrangement relationship of the devices in the substrate processing system 1 shown in FIG. 1, sub-coordinates (X′-Y′-Z′ coordinates) for explaining the arrangement relationship of the devices in the plasma processing apparatus 2 are shown in FIGS. 2 to 6. In the sub-coordinates, the position connected to the vacuum transfer module 13 is set as the front side; the X′ direction is set as the front-rear direction; and the Y′ direction is set as the left-right direction.

The six plasma processing apparatuses 2 connected to the vacuum transfer chamber 14 have the same configuration, and can process the wafers W simultaneously.

The plasma processing apparatus 2 includes a processing chamber 20 having a rectangular planar shape. The processing chamber 20 is configured as an evacuable vacuum chamber. In FIG. 2, a reference numeral 201 denotes a ceiling member of the processing chamber 20, and a reference numeral 202 denotes a chamber body.

On the sidewall on the front side of the chamber body 202, two loading/unloading ports (not shown) connected to the vacuum transfer chamber 14 through the gate valves G are arranged side by side in the left-right direction (the Y′ direction in FIG. 2). The loading/unloading ports are opened and closed by the gate valves G. FIG. 2 is a longitudinal cross-sectional side view of the processing chamber 20 of the plasma processing apparatus 2 which is taken at a position of one of the loading/unloading ports arranged side by side in the left-right direction when viewed from the vacuum transfer chamber 14 side.

The processing chamber 20 has therein two processing spaces S1 and S2 where film formation is performed on the wafer W.

Next, the internal structure of the processing chamber 20 including the processing spaces S1 and S2 will be described. The two processing spaces S1 and S2 have the same structure. Each of the processing spaces S1 and S2 are formed between a mounting table 22 for mounting thereon the wafer W and a gas supply unit 4 disposed to face the mounting table 22. Hereinafter, the processing space S2 will be described with reference to FIG. 2.

The mounting table 22 serves as a lower electrode and has a flat disc shape. The mounting table 22 is made of, e.g., aluminum nitride (AlN), and an electrode 23 made of a metal or a metal mesh is embedded in the mounting table 22. As will be described later, the electrode 23 is connected to a second high frequency power supply 72 for attracting ions in plasma of a processing gas through a matching unit (MU) 70 or the like. The second high frequency power supply 72 corresponds to a high frequency power supply unit for supplying a high frequency power for plasma processing in this example.

In FIG. 2, the mounting table 22 at a processing position is indicated by a solid line, and the mounting table 22 at a transfer position is indicated by a dotted line. At the processing position, the substrate processing (film formation) is performed. At the transfer position, the wafer W is transferred to and from the above-described substrate transfer mechanism 15. A heater 24 for heating the wafer W mounted on the mounting table 22 to a temperature of 60° C. to 600° C. is embedded in the mounting table 22. A power from a power supply (PS) 75 to be described later is supplied to the heater 24. A thermocouple (not shown) that is a sensor unit for measuring the temperature of the mounting table 22 for heating the wafer W is embedded in the mounting table 22.

A plurality of, e.g., three transfer pins 25 are disposed at the bottom surface of the processing chamber 20 to correspond to through holes 26 formed in the mounting table 22, so that the transfer pins 25 can pass therethrough. When the mounting table 22 is lowered to the transfer position, the transfer pins 25 passes through the through-holes 26 and the upper ends of the transfer pins 25 protrude beyond the mounting surface of the mounting table 22. The arrangement of the transfer pins 25 and the shapes of the first and second substrate holders 161 and 162 are set such that they do not interfere with each other during the transfer of the wafer W between the first and second substrate holders 161 and 162 of the substrate transfer mechanism 15.

The center of the disc-shaped mounting table 22 is supported from the bottom surface (back surface) thereof by a support 6. The lower portion of the support 6 protrudes downward while penetrating through the bottom surface (wall) 27 of the processing chamber 20. The support 6 can raise and lower the mounting table 22 by an operation of an elevating mechanism (not shown). The support 6 is connected to a rotation mechanism to be described later, and thus can rotate the mounting table 22 about a vertical axis. The high frequency power from the second high frequency power supply 72, the power from the power supply 75, and the output signal (potential difference generated by the thermocouple) outputted from the thermocouple are inputted and outputted through the support 6.

The substrate holding unit 16 is configured to transfer, e.g., two wafers W, simultaneously to and from the mounting tables 22 in the processing spaces S1 and S2 in cooperation with the transfer pins 25 and the mounting tables 22.

The gas supply unit 4 serving as an upper electrode is disposed at the ceiling member 201 of the processing chamber 20 through a guide member 34 made of an insulating member to face the mounting table 22. The gas supply unit 4 includes a lid 42, a shower plate 43 disposed to face the mounting surface of the mounting table 22, and a gas passageway 44 formed between the lid 42 and the shower plate 43. A gas distribution line 51 is connected to the lid 42. Gas ejection holes 45 formed through the shower plate 43 in a thickness direction thereof are horizontally and vertically arranged to inject gases in a shower pattern.

The upstream side of the gas distribution line 51 connected to the gas supply units 4 of the processing spaces S1 and S2 joins with a common gas supply line 52 and is connected to a gas supply system 50. The gas supply system 50 includes, e.g., a reactant gas (processing gas) supply source (RGS) 53, a purge gas supply source (PGS) 54, a supply source (CGS) 55 of a cleaning gas for removing a film deposited in the processing chamber 20, pipes, valves V1 to V3, flow rate controllers M1 to M3, and the like.

A first high frequency power supply 71 is connected to the shower plate 43 through the matching unit 70. When a high frequency power from the first high frequency power supply 71 is applied to the space between the shower plate (the upper electrode) 43 and the mounting table (the lower electrode) 22, a gas (reactant gas in this example) supplied from the shower plate 43 into the processing spaces S1 and S2 can be converted to plasma by capacitive coupling.

The annular guide member 34 is disposed around each of the processing spaces S1 and S2 to form a slit exhaust port 36 that is opened in a slit shape along the circumferential direction of each of the processing spaces S1 and S2. The guide member 34 is fitted into a recess 204 formed in the chamber body 202, and forms a passage 35 through which the gases discharged from the processing spaces S1 and S2 flow through the slit exhaust port 36. A gas exhaust port (not shown) is formed at the passage 35, and the inside of the plasma processing apparatus 2 is evacuated through a gas exhaust line (not shown) connected to the gas exhaust port.

As described above, in the plasma processing apparatus 2 of this example, the processing spaces S1 and S2 are defined by providing multiple sets of the shower plate 43 and the mounting table 22 in the common processing chamber 20. The film formation is performed in each of the processing spaces S1 and S2. The supports 6 supporting the mounting tables 22 are connected to the rotation mechanism. Various electric powers and signals are inputted and outputted between the mounting tables 22 and the outside through the supports 6. Since the supports 6 to which the high frequency power from the second high frequency power supply 72 is supplied protrude to the outside while penetrating through the processing chamber 20, it is required to provide a mechanism for suppressing the leakage of the high frequency power.

The protruding part protruding to the outside of the processing chamber 20 which includes the support 6 has a relatively complicated structure to be described later. Therefore, it is difficult to disassemble the protruding part at the installation site of the plasma processing apparatus 2 (the substrate processing system 1) during a maintenance operation or the like. Particularly, the substrate processing system 1 shown in FIG. 1 includes six plasma processing apparatuses 2, each having the processing spaces S1 and S2, and twelve mounting tables 22. Accordingly, if the maintenance time for the mounting tables 22 is increased, a considerably long maintenance time is required for one substrate processing system 1.

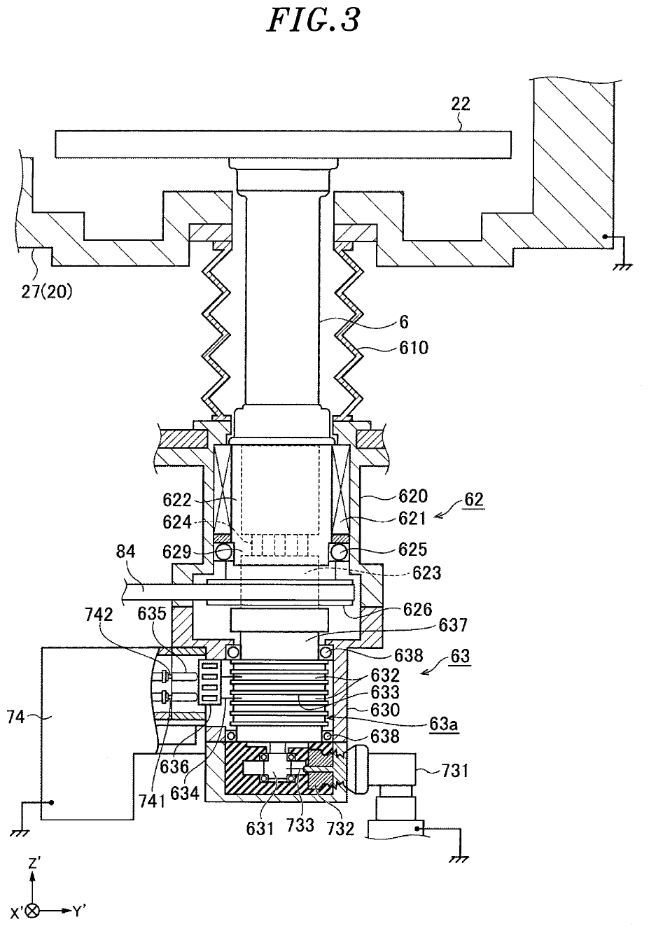

Therefore, the plasma processing apparatus 2 of this example is configured to rotatably hold the support 6 and detach, as one unit, the structure for inputting and outputting various powers or signals to and from the mounting tables 22. Hereinafter, the configuration will be described with reference to FIGS. 3 to 6.

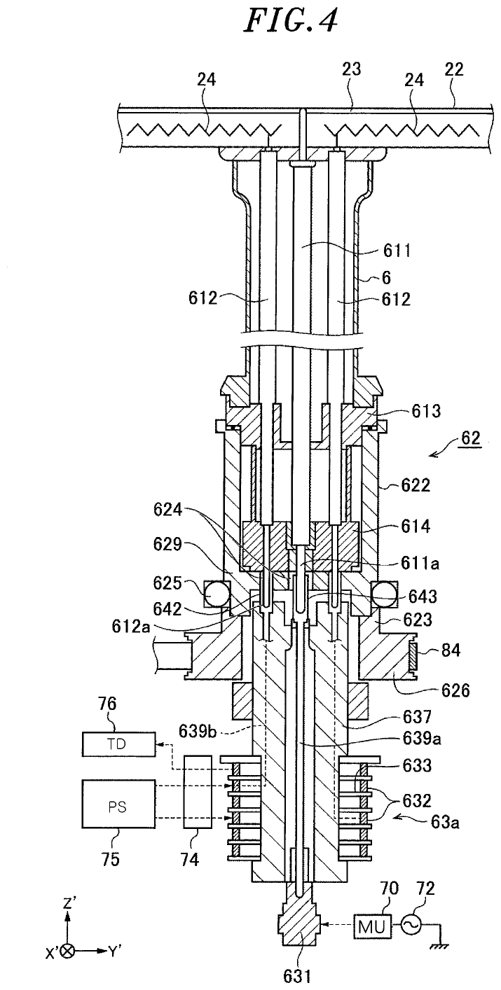

As shown in FIGS. 3 and 4, the support 6 supporting the mounting table 22 from the bottom surfaces thereof protrudes downward while penetrating through the bottom surface 27 of the processing chamber 20. The lower end of the support 6 is connected to an entirely detachable module unit 63 through a coupling unit 62. A mechanism for inputting and outputting various powers or signals to and from the rotating mounting tables 22 is disposed in the module unit 63.

The support 6, the coupling unit 62, and the module unit 63 constitute a supporting shaft unit of this example, and the part positioned below the bottom portion 27 corresponds to the protruding part of the supporting shaft unit.

The coupling unit 62 has a structure in which a cylindrical upper cup 622 that is opened upward and a cylindrical lower cup 623 that is opened downward are vertically connected through a disc-shaped coupling plate 629. The lower end of the support 6 is inserted into the upper cup 622, whereas the upper end of the module unit 63 is inserted into the lower cup 623.

The upper cup 622 is rotatably held in a cylindrical casing 620 through a bearing 625. A bellows 610 is disposed between the upper end surface of the casing 620 and the bottom surface of the processing chamber 20 to surround the opening of the bottom surface 27 through which the support 6 penetrates.

The support 6 penetrates through the bottom surface 27 through the opening, and is inserted into the upper cup 622 while being surrounded by the support 6. The bellows 610 is expanded and contracted by the vertical movement of the mounting table 22. A magnetic fluid seal 621 is disposed above the bearing 625 for rotatably holding the upper cup 622 to separate the vacuum atmosphere in the processing chamber 20 from the external atmosphere.

As shown in FIG. 4, the support 6 has a hollow inner portion, and a high frequency power supply line 611 for supplying a high frequency power to the electrode 23 in the mounting table 22 and a heater power supply line 612 for supplying a power to the heater 24 in the mounting table 22 are disposed in the support 6 to extend in a vertical direction. The lower end portions of the heater power supply line 612 and the high frequency power supply line 611 are held by a common head part 614. When the head part 614 is inserted into the upper cup 622, the head part 614 is guided to the inner peripheral surface of the upper cup 622, and the lower end portions of the heater power supply lines 612 and the high frequency power supply are located at predetermined positions.

Pins 611a and 612a for connection to the module unit 63 are fixedly held to protrude downward from the bottom surface of the head part 614 (the lower ends of the heater power supply line 612 and the high frequency power supply line 611).

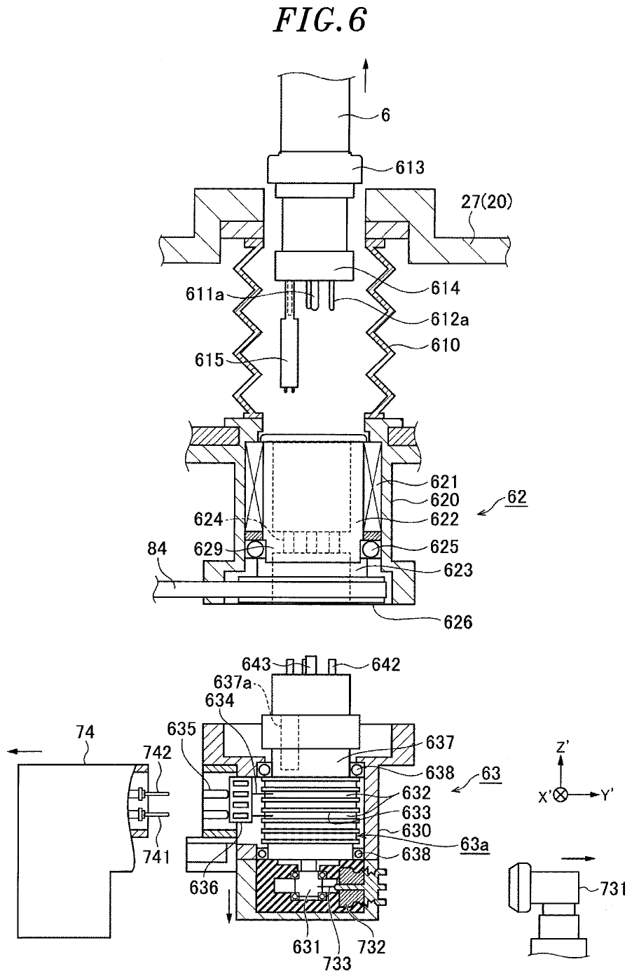

A signal line (not shown) for outputting an output signal (potential difference generated by the thermocouple) of the thermocouple disposed at the mounting table 22 is disposed in the support 6 to extend in the vertical direction. The lower end of the signal line is connected to a contact terminal formed at a bottom surface of a cylindrical connector head 615 penetrating through the head part 614 (see FIG. 6).

A flange 613 that is fitted to the opening of the upper cup 622 and holds the support 6 at a preset height position is disposed at an intermediate height position of the support 6.

As shown in FIG. 4, the module unit 63 includes a top-shaped portion 631 and a rotary cylinder 637 constituting a slip ring for inputting the high frequency power. A slip ring unit 63a is formed at a lower region of the rotary cylinder 637 along a side peripheral surface thereof and constitutes a slip ring for inputting the power for the heater 24 or outputting the output signal of the thermocouple is outputted.

A coaxial socket 732 to which a coaxial connector 731 is detachably attached is disposed at a lower region of the casing 630 of the module unit 63. The coaxial connector 731 is connected to the second high frequency power supply 72 through the matching unit 70 (see FIGS. 3 and 4). The pin of the coaxial socket 732 is connected to a brush 733 in contact with the outer peripheral surface of the top-shaped portion 631. The outer conductor of the coaxial socket 732 is electrically connected to the casing 630, and is grounded through the outer conductor of the coaxial connector 731.

As shown in FIG. 4, the top-shaped portion 631 is connected to a high frequency power supply line 639a. A cylindrical socket 643 through which the pin 611a of the high frequency power supply line 611 on the support 6 side is inserted is disposed at the upper end of the high frequency power supply line 639a. The socket 643 pivotably protrudes upward from the upper surface of the rotary cylinder 637.

The slip ring unit 63a has a structure in which metal rings 632 and insulating plates 633 are alternately stacked in multiple stages.

Some metal rings 632 are connected to the heater power supply line 639b. A cylindrical socket 642 into which the pin 612a of the heater power supply line 612 on the support 6 side is inserted is disposed at the upper end of the heater power supply line 639b. The socket 642 pivotably protrudes upward from the upper surface of the rotary cylinder 637.

Some metal rings 632 are connected to a signal line (not shown) extending vertically in the rotary cylinder 637. The upper end of the signal line is connected to a contact terminal (not shown) disposed at a bottom surface of a socket hole 637a formed at the rotary cylinder 637 to allow insertion of the connector head 615 on the support 6 side.

A brush holder 636 is disposed at the side of the slip ring unit 63a. When a plurality of brushes 634 held by the brush holder 636 are brought into contact with the metal rings 632, the electrical contact for the power supply and the output of the output signal is obtained. The brushes 634 of the brush holder 636 are connected to a socket 635. By connecting plug pins 741 and 742 to the sockets 635, the metal rings 632 are connected to the power supply 75 or a temperature detector (TD) 76 (see FIG. 4). The plug pins 741 and 742 are connected to the power supply 75 and the temperature detector 76 through a noise filter box 74. The housing of the noise filter box 74 is grounded (see FIG. 3).

The rotary cylinder 637 is rotatably held by a bearing 638 disposed at the casing 630.

The upper side of the rotary cylinder 637 can be inserted into the opening of the lower cup 623 on the coupling unit 62 side.

Here, a plurality of communication holes 624 is formed in the coupling plate 629 that connects the upper cup 622 and the lower cup 623 of the coupling unit 62. The pins 611a and 612a on the support 6 side, the connector head 615, and the sockets 643 and 642 on the module unit 63 side can be inserted into the communication holes 624. The pins 611a and 612a and the sockets 643 and 642 are inserted into the communication holes 624 and connected to each other (see FIG. 4).

The connector head 615 is moved downward through the communication hole 624 of the coupling plate 629 and fitted to the socket hole 637a formed at the rotary cylinder 637 on the module unit 63 side (the fitted state not shown).

In the supporting shaft unit, the high frequency power is supplied to the mounting table 22 through the high frequency power supply line 639a. Therefore, it is necessary to suppress the leakage of the high frequency power to the outside Accordingly, the casing 630 of the module unit 63, the casing 620 of the coupling unit 62, and the bellows 610 are made of a conductive metal and are electrically connected to each other. The casings 630 and 620 and the bellows 610 are grounded through the processing chamber 20 in contact with the bellows 610, or through the noise filter box 74 and the coaxial connector 731 in contact with the casing 630. As a result, the casings 630 and 620 and the bellows 610 constitute a high frequency shield that covers the protruding part of the supporting shaft unit which protrudes to the outside of the processing chamber 20.

The above-described configuration is provided in each of the processing spaces S1 and S2 shown in FIG. 2. The supporting shaft unit, the high frequency shield, and the mounting table 22 in one of the processing spaces S1 and S2 (e.g., the processing space S1) constitute a first mounting table unit of this example. The supporting shaft unit, the high frequency shield, and the mounting table 22 disposed in the other processing space (e.g., the processing space S2) constitute a second mounting table unit of this example.

As shown in FIGS. 2, 3 and 5, the supporting shaft unit (the support 6, the upper cup 622 and the lower cup 623 in the coupling unit 62, and the rotational body in the module unit 63) is rotated by a belt-and-pulley mechanism.

In the plasma processing apparatus 2 of this example, using driving pulleys 832a and 832b disposed at a common driving shaft 833, the supporting portions of the driving pulleys 832a and 832b are rotated in order to synchronously rotate the two mounting tables 22 in the processing spaces S1 and S2. A timing belt (driving belt) 84 is wound between the driving pulleys 832a and 832b and passive pulleys 626 of the supporting shaft units. Two belt-and-pulley mechanisms for synchronously driving the two supporting shaft units are configured by rotating the driving shaft 833 using a common driving motor 83.

As shown in FIG. 2, the passive pulleys 626 of the supporting shaft unit in, e.g., the processing space S1, are formed on the outer peripheral surface of the upper region of the rotary cylinder 637 of the module unit 63 to correspond to the height positions of the driving pulleys 832a and 832b stacked vertically. The passive pulley 626 of the supporting shaft unit in the processing space S2 is formed on the outer peripheral surface of the lower cup 623 of the coupling unit 62 (see FIGS. 3, 4, and 6).

In FIG. 2, a reference numeral 831 denotes a casing accommodating the driving pulleys 832a and 832b.

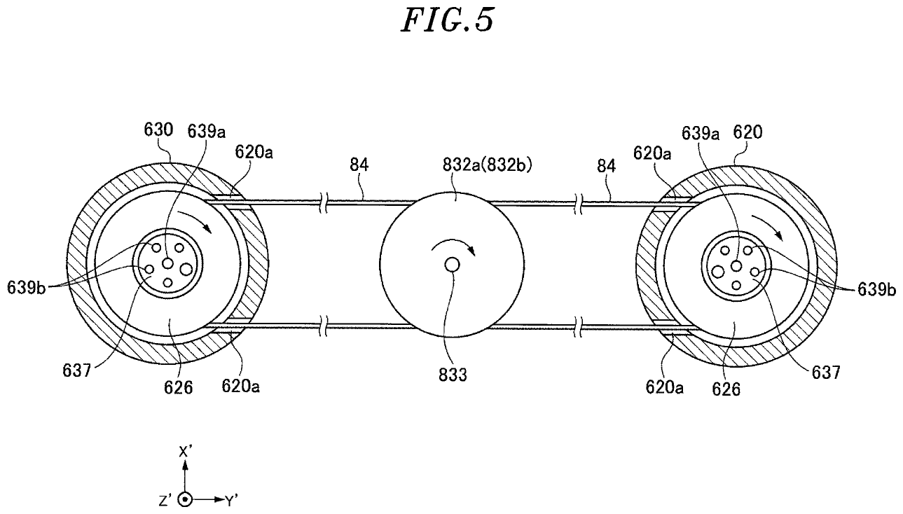

In the case of rotating the supporting shaft units using the belt-and-pulley mechanisms, it is necessary to draw out the timing belt 84 from the high frequency shield (the casing 620 or 630 in this example) to the outside. Therefore, as shown in FIG. 5, slits 620a are formed in the casings 620 and 630 corresponding to the height positions of the passive pulleys 626. The timing belt 84 is drawn out to the outside through the slits 620a.

When the above-described belt-and-pulley mechanisms are driven, it is preferable to minimize the width or the height of the slits 620a within a range that does not affect the operation of the timing belt 84 passing through the slits 620a. By reducing the opening areas of the slits 620a, the leakage of the high frequency power to the outside can be minimized.

As shown in FIG. 2, by employing the belt-and-pulley mechanisms, the driving motor 83 for driving the supporting shaft units can be disposed at a position separated from the slits 620a. Accordingly, the effects of the high frequency power on the driving motor 83 can be suppressed.

As shown in FIG. 2, the supports 6, the module units 63, and the noise filter boxes 74 in the processing spaces S1 and S2 are supported on a supporting table 81. The driving pulleys 832a and 832b, the driving motor 83, and the like constituting the belt-and-pulley mechanisms are supported on the supporting table 81 through a supporting table and a support 85.

By raising and lowering the supporting table 81 using an elevating mechanism (not shown), the entire devices can be raised and lowered and, thus, the mounting tables 22 in the processing chamber 20 can be moved between the wafer transfer position and the wafer processing position.

In the plasma processing apparatus 2 configured as described above, in order to perform the maintenance operation of the supporting shaft unit, the coaxial connector 731 is detached from the coaxial socket 732, and the plug pins 741 and 742 of the noise filter box 74 are pulled out from the module unit 63 as shown in FIG. 6. Then, the module unit 63 is pulled downward to release the connection between the socket 643 and the pin 612a for high frequency power supply, the connection between the socket 642 and the pin 611a for power supply, and the connection between the connector head 615 and the socket hole 637a for output of an output signal.

As a result, the rotational body (the top-shaped portion 631 and the rotary cylinder 637) disposed at the end portion thereof can be detached by dividing the supporting shaft unit in the longitudinal direction. At the same time, the casing 630 disposed at the end portion thereof can be detached by dividing the high frequency shield in the longitudinal direction. At this time, since the rotational body and the casing 630 are integrally formed as the module unit 63, it is not necessary to perform the detaching operation twice to detach them.

The maintenance operation of the module unit 63 having a complicated structure for inputting and outputting various electric powers and signals can be performed by disassembling the module unit 63 in a location separated from the position below the processing chamber 20 where the maintenance operation can be carried out.

By opening the ceiling member 201 of the processing chamber 20 and upwardly pulling out the mounting table 22 and the support 6, the mounting table 22 and the support 6 can be taken out for the maintenance operation.

After the maintenance operation is completed, the position of the support 6 in the circumferential direction is adjusted, and the head part 614 disposed at the lower end of the support 6 is inserted into the upper cup 622. Accordingly, the mounting table 22 is held at a preset height position. On the other hand, the position of the module unit 63 in the circumferential direction is adjusted, and the rotary cylinder 637 is inserted into the lower cup 623. Accordingly, the connection between the heater power supply line 612 and the socket 642, the connection between the pin 611a and the socket 643 for high frequency power supply, and the connection between the connector head 615 and the socket hole 637a for output signal are obtained, and the supporting shaft unit is assembled.

Since the supporting shaft unit can be assembled and dissembled simply by inserting and pulling out the module unit 63, a delicate connection operation using screws or the like is not required, which makes it possible to reduce the risk of dropping screws at the time of changing tools or the like.

As described above, the sockets 643 and 642 are pivotably disposed at the module unit 63. Therefore, even if the positions of the pins 611a and 612a on the support 6 side are displaced within a manufacturing tolerance range, the displacement can be absorbed by the pivoting movement of the sockets 643 and 63. Accordingly, the reliable connection can be obtained.

In order to prevent the separation of the coupling unit 62 and ensure the electrical connection, the casing 630 of the module unit 63 and the casing 620 of the coupling unit 62 may be fastened using screws (not shown) at the flanges. Since the casings 620 and 630 are exposed to the outside, the maintenance operation can be simply carried out compared to the case of connecting the internal components of the supporting shaft unit using screws. In the case of fastening the flanges, it is possible to form grooves on the contact surface between the flanges and improve the conductivity by placing highly conductive metal coils in the grooves.

In accordance with the plasma processing apparatus 2 according to the above-described embodiment, the module unit 63 can be entirely detached to divide each of the supporting shaft unit and the high frequency shield into parts in the longitudinal direction, so that the maintenance operation can be simplified.

The supporting shaft unit may have various configurations to be described below.

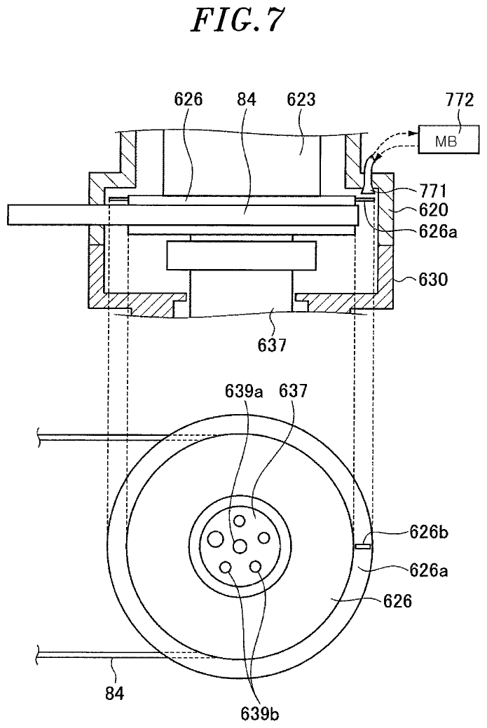

FIG. 7 shows an example in which a dog 626a is disposed along the circumferential direction of the passive pulley 626 driven by the timing belt 84. The rotation position (e.g., home position to start rotation) of the supporting shaft unit (the mounting table 22) can be detected by allowing a light emitting/receiving unit 771 using an optical fiber to detect whether or not light projected on the dog 626a having a slit 626b has been reflected.

By providing a main body (MB) 772 at a position separated from the light emitting/receiving unit 771 through an optical fiber, it is possible to reduce the effects of the noise of the high frequency power on the detection of the rotation position of the supporting shaft unit.

FIG. 7 shows an example in which a light emitting unit for emitting light for detection toward the dog 626a and a light receiving unit for receiving light reflected from the dog 626a are integrally formed as the light emitting/receiving unit 771. However, the present disclosure is not limited thereto, and the light emitting unit and the light receiving unit may be separated provided at different positions.

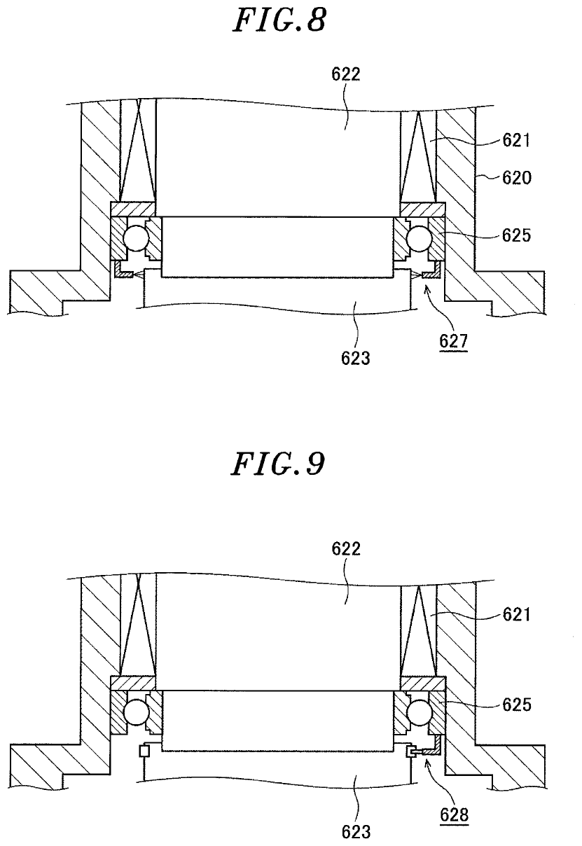

FIGS. 8 and 9 show the configurations for suppressing electrolytic corrosion of the bearings (the bearing 625 between the upper cup 622 and the casing 620 in the illustrated example) disposed between the supporting shaft unit through which the high frequency power flows and the grounded high frequency shield.

FIG. 8 shows an example in which a conducting brush 627 to be in electrical contact with the side peripheral surface of the supporting shaft unit in the circumferential direction is disposed between the outer race of the bearing 625 and the supporting shaft unit (the lower cup 623). FIG. 9 shows an example in which a slip ring 628 is disposed between the outer race of the bearing 625 and the supporting shaft unit (the lower cup 623). Due to the conducting brush 627 and the slip ring 628, the outer race of the bearing 625 and the supporting shaft unit have the same potential, which makes it possible to suppress electrolytic corrosion of the bearing ball. The conducting brush 627 and the slip ring 628 correspond to the equipotential unit of this example.

In the plasma processing apparatus 2, plasma of the processing gas is generated in a state where the first high frequency power supply 71 for plasma generation is connected to the shower plate (the upper electrode) 43 and the second high frequency power supply 72 for attracting ions is connected to the mounting table (the lower electrode) 22. However, the present disclosure is not limited thereto. For example, capacitively coupled plasma may be generated in a state where both of the first high frequency power supply 71 and the second high frequency power supply 72 are connected to the mounting table 22 and the shower plate 43 is grounded. In addition, capacitively coupled plasma may be generated in a state where the first high frequency power supply 71 is connected to the shower plate 43 (upper electrode) and the mounting table 22 (the lower electrode) is grounded. In this case, an impedance adjustment circuit (not shown) is connected instead of the matching unit 70.

Further, inductively coupled plasma may be generated by providing an inductively coupled plasma (ICP) antenna on the upper surface of the ceiling member 201 of the processing chamber 20, or microwave plasma may be generated by providing a microwave generator.

The plasma processing performed in the plasma processing apparatus 2 is not limited to the above-described film formation. For example, the plasma processing may be an etching process for etching the wafer W using plasma of an etching gas, or an ashing process for removing a resist film or the like formed on the surface of the wafer W using plasma of an ashing gas.

The embodiments of the present disclosure are illustrative in all respects and are not restrictive. The above-described embodiments can be embodied in various forms. Further, the above-described embodiments may be omitted, replaced, or changed in various forms without departing from the scope of the appended claims and the gist thereof.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made departing from the spirit of the disclosures. The accompanying claims and their equivalents are intended to cover such forms or modifications as would fall within the scope and spirit of the disclosures.

What is claimed is:

1. A plasma processing apparatus for processing a substrate using plasma of a processing gas, comprising:
a processing chamber where a processing gas supply unit configured to supply the processing gas is disposed;
a mounting table disposed in the processing chamber and configured to mount thereon a substrate as a processing target;
a supporting shaft unit configured to support the mounting table from an opposite surface of a substrate mounting surface, having a protruding part that protrudes outside while penetrating through a wall of the processing chamber, and connected to a rotation mechanism configured to rotate the mounting table about an axis;
a high frequency power supply configured to supply a high frequency power for plasma processing; and
a high frequency shield that covers the protruding part of the supporting shaft unit to suppress leakage of the high frequency power to the outside,
wherein a module unit is configured to be entirely detachable to divide each of the supporting shaft unit and the high frequency shield into parts in a longitudinal direction.

2. The plasma processing apparatus of claim 1, further comprising:
a power supply line disposed along the longitudinal direction of the supporting shaft unit to supply a power to the mounting table and connected through a plug pin and a socket at a position where the module unit is detached.

3. The plasma processing apparatus of claim 2, wherein the socket has a cylindrical shape protruding in a pin direction and is pivotable depending on an arrangement position of the plug pin.

4. The plasma processing apparatus of claim 1, further comprising:
a signal line that is disposed along the longitudinal direction of the supporting shafting unit to transmit an output signal of a sensor disposed at the mounting table and is connected through a plug pin-socket at a position where the module unit is detached.

5. The plasma processing apparatus of claim 4, wherein the module unit is provided with a slip ring for outputting the output signal.

6. The plasma processing apparatus of claim 1, wherein the rotation mechanism includes driving pulleys, passive pulleys disposed on an outer peripheral surface of the protruding part of the supporting shaft unit, and a driving belt wound around the driving pulleys and the passive pulleys, and
slits through which the driving belt passes are formed at the high frequency shield.

7. The plasma processing apparatus of claim 6, wherein a first mounting table unit and a second mounting table unit, each including the mounting table, the supporting shaft unit, and the high frequency shield, are disposed in the processing chamber, and
the mounting tables of the first mounting table unit and the second mounting table unit are rotated synchronously by providing the driving pulleys of the rotation mechanism for driving the supporting shaft units of the first mounting unit and the second mounting unit at a common driving shaft.

8. The plasma processing apparatus of claim 1, further comprising:
a dog disposed on a side surface of the protruding part of the supporting shaft unit and configured to detect a rotation angle of the mounting table;
a light emitting/receiving unit disposed at the high frequency shield and configured to irradiate detection light to the dog for detecting a direction of the dog and to receive the detection light irradiated to the dog; and
a detection unit disposed at a position separated from the high frequency shield and to which a detection signal of the detection light received by the light receiving unit is inputted.

9. The plasma processing apparatus of claim 1, further comprising:
a bearing disposed between the high frequency shield and the supporting shaft unit and configured to rotatably hold the supporting shaft unit; and
an equipotential unit configured to equalize potentials of the high frequency shield and the supporting shaft unit.

10. The plasma processing apparatus of claim 9, wherein the equipotential unit is a brush electrode disposed between an outer race of the bearing and the supporting shaft unit.

11. The plasma processing apparatus of claim 9, wherein the equipotential unit is a slip ring disposed between the high frequency shield and the supporting shaft unit.

12. A maintenance method of a plasma processing apparatus for processing a substrate using plasma of a processing gas, the plasma processing apparatus including a processing chamber having a processing gas supply unit configured to supply the processing gas, a mounting table disposed in the processing chamber and configured to mount thereon a substrate as a processing target, a supporting shaft unit configured to support the mounting table from an opposite surface of a substrate mounting surface and having a protruding part protruding outside while penetrating through a wall of the processing chamber and connected to a rotation mechanism configured to rotate the mounting table about an axis, a high frequency power supply configured to supply a high frequency power for plasma processing, and a high frequency shield that covers the protruding part of the supporting shaft unit to suppress leakage of the high frequency power to the outside,
the maintenance method comprising:
detaching an integrally formed module unit which is configured to divide each of the supporting shaft unit and the high frequency shield into parts in a longitudinal direction for a maintenance operation.
